(19) United States
(12) Patent Application Publication
(10) Pub. No.: US 2025/0212656 A1
(43) Pub. Date: Jun. 26, 2025

(54) Display Device

(71) Applicant: LG Display Co., Ltd., Seoul (KR)

(72) Inventors: YeongHo Yun, Seoul (KR); Jeongmin Park, Paji-si (KR)

(21) Appl. No.: 18/824,288

(22) Filed: Sep. 4, 2024

(30) Foreign Application Priority Data
Dec. 20, 2023 (KR) 10-2023-0187616

(51) Int. Cl. H10K 59/80; H10K 59/124

(52) U.S. Cl. CPC H10K 59/873; H10K 59/124

(57) ABSTRACT

A display device includes a substrate including a display area, an optical area disposed in the display area and including a through-hole, and a non-display area configured to surround the display area, a plurality of insulation layers disposed on the substrate, at least one dam disposed on the plurality of insulation layers, and at least one anti-connection part disposed on the plurality of insulation layers and disposed to be closer to the through-hole than the at least one dam, in which first trenches are disposed in some of the plurality of insulation layers that overlaps the at least one anti-connection part in the optical area. Therefore, it is possible to inhibit cracks, which occur because of external interference in an optical area, from propagating.

### CROSS-REFERENCE TO RELATED APPLICATION

This application claims the priority of Republic of Korea Patent Application No. 10-2023-0187616 filed on Dec. 20, 2023, which is hereby incorporated by reference in its entirety.

### FIELD

The present specification relates to a display device, and more particularly, to a display device capable of blocking a crack propagation path in an area in which a camera or sensor is disposed.

### DESCRIPTION OF THE RELATED ART

Display devices, which visually display electrical information signals, are being rapidly developed in accordance with the entry into the information era. Various studies are being continuously conducted to develop a variety of display devices which are thin and lightweight, consume low power, and have improved performance.

As the representative display devices, there may be a liquid crystal display (LCD) device, a field emission display (FED) device, an electrowetting display (EWD) device, an organic light-emitting display (OLED) device, and the like.

An electroluminescent display device, as the representative organic light-emitting display device, refers to a display device that autonomously emits light. Unlike a liquid crystal display device, the electroluminescent display device does not require a separate light source and thus may be manufactured as a lightweight, thin display device. In addition, the electroluminescent display device is advantageous in terms of power consumption because the electroluminescent display device operates at a low voltage. Further, the electroluminescent display device is expected to be adopted in various fields because the electroluminescent display device is also excellent in implementation of colors, response speeds, viewing angles, and contrast ratios (CRs).

### SUMMARY

An object to be achieved by one embodiment of the present specification is to provide a display device capable of suppressing the propagation of cracks caused by external interference in an area in which a camera or sensor is disposed.

An object to be achieved by another embodiment of the present specification is to provide a display device capable of ensuring a product yield and reliability.

Objects of the present disclosure are not limited to the above-mentioned objects, and other objects, which are not mentioned above, can be clearly understood by those skilled in the art from the following descriptions.

A display device according to an embodiment of the present specification includes a substrate including a display area, an optical area disposed in the display area and including a through-hole, and a non-display area configured to surround the display area, a plurality of insulation layers disposed on the substrate, at least one dam disposed on the plurality of insulation layers, and at least one anti-connection part disposed on the plurality of insulation layers and disposed to be closer to the through-hole than the at least one dam, in which first trenches are disposed in some of the plurality of insulation layers that overlaps the at least one anti-connection part in the optical area.

Other detailed matters of the exemplary embodiments are included in the detailed description and the drawings.

According to the display device according to the embodiment of the present specification, the plurality of anti-connection parts is provided on the peripheral portion of the through-hole, thereby inhibiting penetration of moisture and oxygen introduced from the through-hole. The suppression part may block the movement paths for moisture and oxygen by disconnecting the organic common layer, i.e., the light-emitting layer of the light-emitting element disposed on the front surface of the display panel.

According to the display device according to the embodiment of the present specification, the plurality of dams may be disposed in the vicinity of the plurality of anti-connection parts to inhibit the organic insulation layer of the encapsulation layer from overflowing into the camera hole. The plurality of dams may suppress the contamination of the camera hole area, which may occur when the organic insulation layer overflows into the camera hole, and suppress interference with the camera to be disposed in the through-hole.

According to the display device according to the embodiment of the present specification, the trenches are disposed by partially etching the plurality of inorganic insulation layers that overlaps the plurality of anti-connection parts, such that the path, through which the crack propagates, may be blocked even though the through-hole cracks, and the crack propagation may be suppressed.

The effects according to the present disclosure are not limited to the contents exemplified above, and more various effects are included in the present specification.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a block diagram of a display device according to an embodiment of the present specification;

FIG. 2 is a cross-sectional view taken along line II-II′ in FIG. 1 according to an embodiment of the present specification;

FIG. 3 is an enlarged top plan view of area A in FIG. 1 according to an embodiment of the present specification;

FIG. 4 is an enlarged top plan view of area B in FIG. 3 according to an embodiment of the present specification;

FIG. 5 is a cross-sectional view taken along line V-V′ in FIG. 4 according to an embodiment of the present specification;

FIG. 6A is an enlarged cross-sectional view of area C in FIG. 5 according to the embodiment of the present specification.

FIG. 6B is a cross-sectional view of a display device according to another embodiment of the present specification;

FIG. 6C is a cross-sectional view of a display device according to still another embodiment of the present specification;

FIG. 6D is a cross-sectional view of a display device according to yet another embodiment of the present specification;

FIG. 6E is a cross-sectional view of a display device according to still yet another embodiment of the present specification;

FIG. 7A is a cross-sectional view of a display device according to a further embodiment of the present specification;

FIG. 7B is a cross-sectional view of a display device according to another further embodiment of the present specification;

FIG. 7C is a cross-sectional view of a display device according to still another further embodiment of the present specification; and

FIG. 7D is a cross-sectional view of a display device according to yet another further embodiment of the present specification.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the exemplary embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “comprising” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, various exemplary embodiments of the present disclosure will be described in detail with reference to the accompanying drawings.

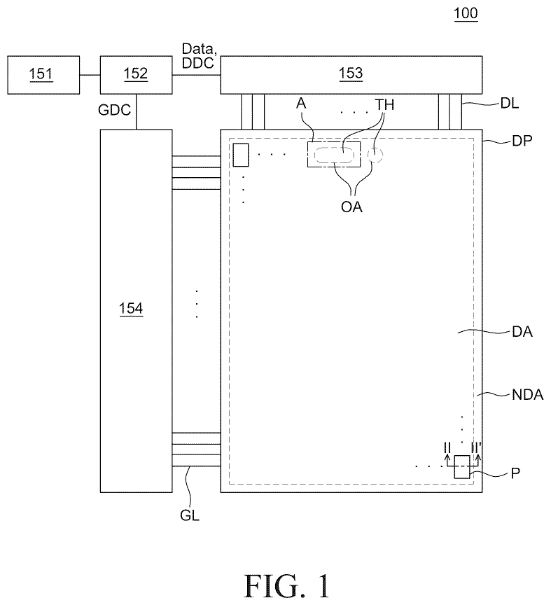

FIG. 1 is a block diagram of a display device according to an embodiment of the present specification.

With reference to FIG. 1, a display device 100 of an embodiment of the present specification may include an image processing part 151, a timing controller 152, a data drive part 153, a gate drive part 154, and a display panel DP.

In this case, the image processing part 151 may output a data signal DATA, a data enable signal DE, and the like supplied from the outside. The image processing part 151 may output one or more of a vertical synchronizing signal, a horizontal synchronizing signal, and a clock signal in addition to the data enable signal DE.

The timing controller 152 receives the data signal DATA in addition to the data enable signal DE or the driving signals including the vertical synchronizing signal, the horizontal synchronizing signal, and the clock signal from the image processing part 151. On the basis of the driving signal, the timing controller 152 may output a gate timing control signal GDC for controlling an operation timing of the gate drive part 154 and output a data timing control signal DDC for controlling an operation timing of the data drive part 153.

In addition, in response to the data timing control signal DDC supplied from the timing controller 152, the data drive part 153 (e.g., data driver or data driver circuit) may sample and latch the data signal DATA supplied from the timing controller 152, convert the data signal DATA into a gamma reference voltage, and output the gamma reference voltage. The data drive part 153 may output the data signal DATA through data lines DL1 to DLn.

In addition, the gate drive part 154 (e.g., a gate driver or gate driver circuit) may output the gate signal while shifting a level of the gate voltage in response to the gate timing control signal GDC supplied from the timing controller 152. The gate drive part 154 may output the gate signal through gate lines GL1 to GLm.

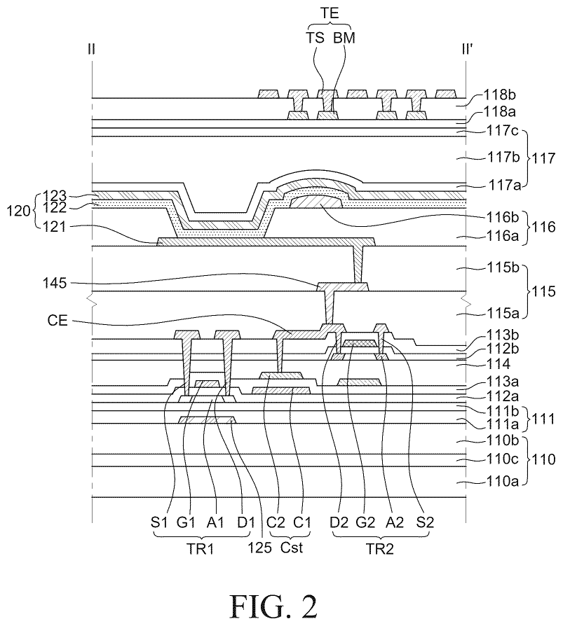

The display panel DP may display an image as a pixel P emits light in response to the data signal DATA and the gate signal supplied from the data drive part 153 and the gate drive part 154. A detailed structure of the pixel P will be described in detail with reference to FIG. 2.

The display panel DP may include a display area DA, an optical area OA disposed in the display area DA and including through-holes TH, and a non-display area NDA configured to surround the display area DA.

The display area DA is an area of the display panel DP in which images are displayed.

A plurality of pixels P and a circuit for operating the plurality of pixels P may be disposed in the display area DA. A pixel P is a minimum unit that constitutes the display area DA. The display element may be disposed in each of the plurality of pixels P. For example, an organic light-emitting element including an anode, a light-emitting layer, and a cathode may be disposed in each of the plurality of pixels P. However, the present disclosure is not limited thereto. In addition, the circuit for operating the plurality of pixels P may include driving elements, lines, and the like. For example, the circuit may include a thin-film transistor, a storage capacitor, a gate line, a data line, and the like. However, the present disclosure is not limited thereto.

The optical area OA is an area disposed in the display area DA, and the through-holes TH may be disposed in the optical area OA. The through-hole TH may be disposed in the display area DA of the display panel DP, thereby reducing a bezel area, which is a non-display area NDA, and maximizing the display area DA. A design product with the maximized display area DA maximizes a degree of screen immersion of the user, thereby improving an aesthetic appearance.

The through-hole TH may be formed to correspond to an optical electronic device such as a camera or optical sensor.

FIG. 1 illustrates two through-holes TH. However, the present disclosure is not limited thereto. The number of through-holes TH may be provided variously. For example, one or two holes are disposed in the display area DA. A camera may be disposed in a first hole, and a distance detection sensor, a face recognition sensor, or a wide angle camera may be disposed in a second hole.

The non-display area NDA is an area in which no image is displayed.

The non-display area NDA may be bent, such that the non-display area NDA is not visible from a front surface. The non-display area NDA may be covered by a casing (not illustrated). The non-display area NDA is called a bezel area.

FIG. 1 illustrates that the non-display area NDA surrounds the display area DA having a quadrangular shape. However, the shapes and arrangements of the display area DA and the non-display area NDA are not limited to the example illustrated in FIG. 1. That is, the display area DA and the non-display area NDA may be suitable for the design of an electronic device equipped with the display device 100. For example, an exemplary shape of the display area DA may also be a pentagonal shape, a hexagonal shape, a circular shape, an elliptical shape, or the like.

Various lines and circuits for operating the organic light-emitting element in the display area DA may be disposed in the non-display area NDA. For example, the non-display area NDA may include link lines for transmitting signals to the plurality of subpixels and the circuit in the display area DA. The non-display area NDA may include gate-in-panel (GIP) lines or drive ICs such as the gate drive part 154 and the data drive part 153. However, the present disclosure is not limited thereto.

The display device 100 may further include various additional elements configured to generate various signals or operate the pixel in the display area DA. The additional elements for operating the pixel may include an inverter circuit, a multiplexer, an electrostatic discharge (ESD) circuit, and the like. The display device 100 may also include additional elements related to functions other than the function of operating the pixel. For example, the display device 100 may further include additional elements that provide a touch detection function, a user certification function (e.g., fingerprint recognition), a multi-level pressure detection function, a tactile feedback function, and the like. The above-mentioned additional elements may be positioned in the non-display area NDA and/or an external circuit connected to a connection interface.

Hereinafter, a cross-sectional structure of the display area DA of the display device 100 will be described in more detail with reference to FIG. 2.

FIG. 2 is a cross-sectional view illustrating a cross-sectional structure of one pixel disposed in the display area according to the embodiment of the present specification.

The display device 100 according to the embodiment of the present specification may include a substrate 110, a first buffer layer 111, a first thin-film transistor TR1, a second thin-film transistor TR2, a first gate insulation layer 112a, a first interlayer insulation layer 113a, a second buffer layer 114, a second gate insulation layer 112b, a second interlayer insulation layer 113b, a connection electrode CE, a first planarization layer 115a, a second planarization layer 115b, an auxiliary electrode 145, a bank 116a, a spacer 116b, an anode 121, a light-emitting layer 122, a cathode 123, an encapsulation layer 117, and a touch detection part.

The substrate 110 serves to support and protect the components of the flexible display device that are disposed above the substrate 110.

The substrate 110 is a component for supporting various constituent elements included in the display device 100 and may be made of an insulating material. The substrate 110 may include a first substrate 110a, a second substrate 110b, and an interlayer insulation film 110c. The interlayer insulation film 110c may be disposed between the first substrate 110a and the second substrate 110b. As described above, the substrate 110 is configured by the first substrate 110a, the second substrate 110b, and the interlayer insulation film 110c, which may suppress moisture penetration. For example, the first substrate 110a and the second substrate 110b may each be a polyimide (PI) substrate, and the interlayer insulation film 110c may be configured as a single layer made of silicon nitride (SiNx) or silicon oxide (SiOx) or a multilayer including the above-mentioned layers.

A light-blocking layer 125 may be disposed on the substrate 110.

The first buffer layer 111 may be disposed on the substrate 110 while covering the light-blocking layer 125. Specifically, a multi-buffer layer 111a may be disposed on the substrate 110 while covering the light-blocking layer 125, and an active buffer layer 111b may be disposed on the multi-buffer layer 111a.

The multi-buffer layer 111a may delay diffusion of moisture or oxygen having penetrated into the substrate 110 and include at least any one of silicon nitride (SiNx) and silicon oxide (SiOx).

The active buffer layer 111b may protect a first active layer A1 and suppress various types of defects introduced from the substrate 110. For example, the active buffer layer 111b may include at least any one of a-Si, silicon nitride (SiNx), and silicon oxide (SiOx).

The first thin-film transistor TR1 may be disposed on the first buffer layer 111. The first thin-film transistor TR1 may include the first active layer A1, a first gate electrode G1, a first source electrode S1, and a first drain electrode D1. In this case, in accordance with design of a pixel circuit, the first source electrode S1 may be a first drain electrode, and the first drain electrode D1 may be a first source electrode.

The first active layer A1 may be disposed on the first buffer layer 111 so as to overlap the light-blocking layer 125. The first active layer A1 may include amorphous silicon or polysilicon (polycrystalline silicon). For example, the first active layer A1 may include a low-temperature polysilicon (LTPS). For example, because a polysilicon material has high mobility (100 cm²/Vs or more), low energy power consumption, and excellent reliability, the polysilicon material may be applied to gate drivers and/or multiplexers (MUX) for driving elements for operating thin-film transistors for display elements. In the display device 100 according to the embodiment of the present specification, the polysilicon material may be applied to a first active layer A1 of the thin-film driving transistor. However, the present disclosure is not limited thereto. For example, the polysilicon material may also be applied to a second active layer A2 of the switching thin-film transistor in accordance with the properties of the display device 100. The first active layer A1 may be formed by depositing an amorphous silicon (a-Si) material on the first buffer layer 111, forming polysilicon by performing a dehydration process and a crystallization process, and then patterning the polysilicon. In this case, the first active layer A1 may include a first channel area in which a channel is formed when the first thin-film transistor TR1 operates, and a first source area and a first drain area disposed at two opposite sides of the first channel area. The first source area means a portion of the first active layer A1 connected to the first source electrode S1, and the first drain area means a portion of the first active layer A1 connected to the first drain electrode D1. For example, the first source area and the first drain area may be configured by doping the first active layer A1 with ions (impurities). The first source area and the first drain area may be formed by doping the polysilicon material with ions. The first channel area may mean a portion in which the polysilicon material remains without being subjected to the ion doping.

The first gate insulation layer 112a may be disposed on the first active layer A1. The first gate insulation layer 112a may be configured as a single layer made of silicon nitride (SiNx) or silicon oxide (SiOx) or a multilayer including the above-mentioned layers. The first gate insulation layer 112a may have contact holes through which the first source electrode S1 and the first drain electrode D1 of the first thin-film transistor TR1 are respectively connected to the first source area and the first drain area of the first active layer A1 of the first thin-film transistor TR1.

The first gate electrode G1 of the first thin-film transistor TR1 and a first capacitor electrode C1 of a storage capacitor Cst may be disposed on the first gate insulation layer 112a.

In this case, the first gate electrode G1 and the first capacitor electrode C1 may each be configured as a single layer or multilayer made of any one of molybdenum (Mo), copper (Cu), titanium (Ti), aluminum (Al), chromium (Cr), gold (Au), nickel (Ni), and neodymium (Nd) or an alloy thereof. The first gate electrode G1 may be formed on the first gate insulation layer 112a so as to overlap the first channel area of the first active layer A1 of the first thin-film transistor TR1.

The first capacitor electrode C1 may be excluded on the basis of the operating properties of the display device 100 and the structure, type, and the like of the thin-film transistor. The first gate electrode G1 and the first capacitor electrode C1 may be formed by the same process. Further, the first gate electrode G1 and the first capacitor electrode C1 may be made of the same material and formed on the same layer.

The first interlayer insulation layer 113a may be disposed above the first gate insulation layer 112a, the first gate electrode G1, and the first capacitor electrode C1. The first interlayer insulation layer 113a may be configured as a single layer made of silicon nitride (SiNx) or silicon oxide (SiOx) or a multilayer including the above-mentioned layers. Further, the first interlayer insulation layer 113a may have a contact hole through which the first source area and the first drain area of the first active layer A1 of the first thin-film transistor TR1 are exposed.

A second capacitor electrode C2 of the storage capacitor Cst may be disposed on the first interlayer insulation layer 113a. The second capacitor electrode C2 may be configured as a single layer or multilayer made of any one of molybdenum (Mo), copper (Cu), titanium (Ti), aluminum (Al), chromium (Cr), gold (Au), nickel (Ni), neodymium (Nd), and an alloy thereof. The second capacitor electrode C2 may be formed on the first interlayer insulation layer 113a so as to overlap the first capacitor electrode C1. In addition, the second capacitor electrode C2 may be made of the same material as the first capacitor electrode C1. The second capacitor electrode C2 may be excluded on the basis of the operating properties of the display device 100 and the structure, type, and the like of the thin-film transistor.

The second buffer layer 114 may be disposed on the first interlayer insulation layer 113a and the second capacitor electrode C2. The second buffer layer 114 may be configured as a single layer made of silicon nitride (SiNx) or silicon oxide (SiOx) or a multilayer including the above-mentioned layers. The second buffer layer 114 may have a contact hole through which the first source area and the first drain area of the first active layer A1 of the first thin-film transistor TR1 are exposed. In addition, the second buffer layer 114 may have a contact hole through which the second capacitor electrode C2 of the storage capacitor Cst is exposed.

The second buffer layer 114 may be configured as a multilayer. However, the present disclosure is not limited thereto.

A second active layer A2 of the second thin-film transistor TR2 may be disposed on the second buffer layer 114. In this case, the second thin-film transistor TR2 may include the second active layer A2, the second gate insulation layer 112b, a second gate electrode G2, a second source electrode S2, and a second drain electrode D2. In this case, in accordance with design of the pixel circuit, the second source electrode S2 may be a drain electrode, and the second drain electrode D2 may be a source electrode.

In addition, the second active layer A2 may include a second channel area in which a channel is formed when the second thin-film transistor TR2 operates, and a second source area and a second drain area disposed at two opposite sides of the second channel area. The second source area may mean a portion of the second active layer A2 connected to the second source electrode S2, and the second drain area may mean a portion of the second active layer A2 connected to the second drain electrode D2.

The second active layer A2 may be made of an oxide semiconductor. The oxide semiconductor material is a material having a larger band gap than a silicon material and has a low off-current because electrons cannot pass through the band gap in an OFF state. Therefore, the thin-film transistor including the active layer made of the oxide semiconductor may be suitable for a switching thin-film transistor that maintains the short ON time and the long OFF time. However, the present disclosure is not limited thereto. The oxide semiconductor may also be applied to the thin-film driving transistor in accordance with the properties of the display device 100. Further, because the oxide semiconductor material has a low off-current and may decrease a magnitude of an auxiliary capacity, the oxide semiconductor material is suitable for a high-resolution display element. For example, the second active layer A2 may be made of a metal oxide, for example, various metal oxides such as indium-gallium-zinc oxide (IGZO). In this case, the description has been made on the assumption that the second active layer A2 of the second thin-film transistor TR2 is made of IGZO among various metal oxides. However, the present disclosure is not limited thereto. The second active layer A2 of the second thin-film transistor TR2 may be made of another metal oxide, such as indium-zinc oxide (IZO), indium-gallium-tin oxide (IGTO), or indium-gallium oxide (IGO), instead of IGZO.

The second active layer A2 may be formed by depositing a metal oxide on the second buffer layer 114, performing a heat treatment process for stabilization, and then patterning the metal oxide.

The second gate insulation layer 112b may be disposed on the entire substrate 110 including the second active layer A2. For example, the second gate insulation layer 112b may be configured as a single layer made of silicon nitride (SiNx) or silicon oxide (SiOx) or a multilayer including the above-mentioned layers.

The second gate electrode G2 may be disposed on the second gate insulation layer 112b.

The second gate electrode G2 may be configured as a single layer or multilayer made of any one of molybdenum (Mo), copper (Cu), titanium (Ti), aluminum (Al), chromium (Cr), gold (Au), nickel (Ni), neodymium (Nd), and an alloy thereof.

For example, the second gate electrode G2 is formed by forming a metallic material on the second gate insulation layer 112b, forming a photoresist pattern on the metallic material, and then wet-etching the metallic material by using the photoresist pattern as a mask. A material, which selectively etches molybdenum (Mo), copper (Cu), titanium (Ti), aluminum (Al), chromium (Cr), gold (Au), nickel (Ni), and neodymium (Nd), or an alloy thereof, which constitutes the metallic material and does not etch the insulating material, may be used as a wet etching liquid for etching the metallic material.

The second interlayer insulation layer 113b may be disposed on the second gate insulation layer 112b and the second gate electrode G2. The second interlayer insulation layer 113b may have a contact hole through which the first active layer A1 of the first thin-film transistor TR1 and the second active layer A2 of the second thin-film transistor TR2 are exposed. For example, the second interlayer insulation layer 113b may have a contact hole through which the first source area and the first drain area of the first active layer A1 of the first thin-film transistor TR1 are exposed. The second interlayer insulation layer 113b may have a contact hole through which the second source area and the second drain area of the second active layer A2 of the second thin-film transistor TR2 are exposed.

The second interlayer insulation layer 113b may be configured as a single layer made of silicon nitride (SiNx) or silicon oxide (SiOx) or a multilayer including the above-mentioned layers.

The connection electrode CE, the first source electrode S1 and the first drain electrode D1 of the first thin-film transistor TR1, and the second source electrode S2 and the second drain electrode D2 of the second thin-film transistor TR2 may be disposed on the second interlayer insulation layer 113b.

The connection electrode CE may be electrically connected to the second drain electrode D2 of the second thin-film transistor TR2. Further, the connection electrode CE may be electrically connected to the second capacitor electrode C2 of the storage capacitor Cst through contact holes formed in the second buffer layer 114 and the second interlayer insulation layer 113b. That is, the connection electrode CE may serve to electrically connect the second capacitor electrode C2 of the storage capacitor Cst and the second drain electrode D2 of the second thin-film transistor TR2.

In this case, the first source electrode S1 and the first drain electrode D1 of the first thin-film transistor TR1 may be connected to the first active layer A1 of the first thin-film transistor TR1 through contact holes formed in the first gate insulation layer 112a, the first interlayer insulation layer 113a, the second buffer layer 114, and the second interlayer insulation layer 113b.

The second source electrode S2 and the second drain electrode D2 of the second thin-film transistor TR2 may be connected to the second active layer A2 through a contact hole formed in the second interlayer insulation layer 113b.

The connection electrode CE, the first source electrode S1 and the first drain electrode D1 of the first thin-film transistor TR1, and the second source electrode S2 and the second drain electrode D2 of the second thin-film transistor TR2 may be formed by the same process and made of the same material.

For example, the connection electrode CE, the first source electrode S1 and the first drain electrode D1 of the first thin-film transistor TR1, and the second source electrode S2 and the second drain electrode D2 of the second thin-film transistor TR2 may each configured as a single layer or multilayer made of any one of molybdenum (Mo), copper (Cu), titanium (Ti), aluminum (Al), chromium (Cr), gold (Au), nickel (Ni), and neodymium (Nd) or an alloy thereof. For example, the connection electrode CE, the first source electrode S1 and the first drain electrode D1 of the first thin-film transistor TR1, and the second source electrode S2 and the second drain electrode D2 of the second thin-film transistor TR2 may each have a three-layer structure including titanium (Ti)/aluminum (Al)/titanium (Ti). However, the present disclosure is not limited thereto.

The connection electrode CE may be integrally connected to the second drain electrode D2 of the second thin-film transistor TR2. However, the present disclosure is not limited thereto.

The first planarization layer 115a may be disposed above the connection electrode CE, the first source electrode S1 and the first drain electrode D1 of the first thin-film transistor TR1, the second source electrode S2 and the second drain electrode D2 of the second thin-film transistor TR2, and the second interlayer insulation layer 113b.

The first planarization layer 115a may be an organic layer for planarizing and protecting an upper portion of the first thin-film transistor TR1 and an upper portion of the second thin-film transistor TR2. For example, the first planarization layer 115a may be made of an organic material such as acrylic resin, epoxy resin, phenolic resin, polyamide resin, and polyimide resin.

The auxiliary electrode 145 may be disposed on the first planarization layer 115a. The auxiliary electrode 145 may be connected to the second drain electrode D2 of the second thin-film transistor TR2 through a contact hole of the first planarization layer 115a. The auxiliary electrode 145 may serve to electrically connect the second thin-film transistor TR2 and an anode 121. Further, the auxiliary electrode 145 may be configured as a single layer or multilayer made of any one of molybdenum (Mo), copper (Cu), titanium (Ti), aluminum (Al), chromium (Cr), gold (Au), nickel (Ni), neodymium (Nd), and an alloy thereof. The auxiliary electrode 145 may be made of the same material as the second source electrode S2 and the second drain electrode D2 of the second thin-film transistor TR2.

The second planarization layer 115b may be disposed above the auxiliary electrode 145 and the first planarization layer 115a. For example, the second planarization layer 115b may be made of an organic material such as acrylic resin, epoxy resin, phenolic resin, polyamide resin, and polyimide resin.

A light-emitting element 120 may be disposed on the second planarization layer 115b.

The anode 121 may be disposed on the second planarization layer 115b. In this case, the anode 121 may be electrically connected to the auxiliary electrode 145 through a contact hole provided in the second planarization layer 115b. The anode 121 may be made of a metallic material.

In case that the display device 100 is a top-emission type display device in which light emitted from the light-emitting element 120 propagates toward an upper side of the substrate 110 on which the light-emitting element 120 is disposed, the anode 121 may further include a transparent conductive layer, and a reflective layer disposed on the transparent conductive layer. For example, the transparent conductive layer may be made of transparent conducting oxide such as ITO or IZO. For example, the reflective layer may be made of silver (Ag), aluminum (Al), gold (Au), molybdenum (Mo), tungsten (W), chromium (Cr), or an alloy thereof.

A bank 116 may be disposed while covering the anode 121. A portion of the bank 116a, which corresponds to the light-emitting area of the subpixel, may be opened. A part of the anode 121 may be exposed through the opened portion (hereinafter, referred to as an open area) of the bank 116a. In this case, the bank 116a may be made of an inorganic insulating material such as silicon nitride (SiNx) or silicon oxide (SiOx), or an organic insulating material such as benzocyclobutene-based resin, acrylic resin, or imide-based resin. However, the present disclosure is not limited thereto. The spacer 116b may be further disposed on the bank 116a.

The light-emitting layer 122 may be disposed in the open area of the bank 116a and an area at the periphery of the open area. Therefore, the light-emitting layer 122 may be disposed on the anode 121 exposed through the open area of the bank 116.

The cathode 123 may be disposed on the light-emitting layer 122.

The light-emitting element 120 may be formed by the anode 121, the light-emitting layer 122, and the cathode 123. The light-emitting layer 122 may include a plurality of organic films.

An encapsulation layer 117 may be positioned on the light-emitting element 120.

The encapsulation layer 117 may have a single-layer structure or a multilayer structure. For example, the encapsulation layer 117 may include a first encapsulation layer 117a, a second encapsulation layer 117b, and a third encapsulation layer 117c.

In this case, the first encapsulation layer 117a and the third encapsulation layer 117c may each be made of an inorganic film, and the second encapsulation layer 117b may be made of an organic film. Among the first encapsulation layer 117a, the second encapsulation layer 117b, and the third encapsulation layer 117c, the second encapsulation layer 117b may be thickest and serve as a planarization layer.

The first encapsulation layer 117a may be disposed on the cathode 123 and closest to the light-emitting element 120. The first encapsulation layer 117a may be made of an inorganic insulating material that may be deposited at a low temperature. For example, the first encapsulation layer 117a may be made of silicon nitride (SiNx), silicon oxide (SiOx), silicon oxynitride (SiON), aluminum oxide (Al₂O₃), or the like. Because the first encapsulation layer 117a is deposited in a low-temperature ambience, it is possible to suppress damage to the light-emitting layer 122 made of an organic material vulnerable to a high-temperature ambience during a deposition process.

The second encapsulation layer 117b may have a smaller area than the first encapsulation layer 117a. In this case, the second encapsulation layer 117b may be formed to expose two opposite ends of the first encapsulation layer 117a. The second encapsulation layer 117b may serve as a buffer for mitigating stress between the layers caused when the flexible display device is bent. The second encapsulation layer 117b may serve to improve the planarization performance.

For example, the second encapsulation layer 117b may be made of an organic insulating material such as acrylic resin, epoxy resin, polyimide, polyethylene, or silicon oxycarbon (SiOC). For example, the second encapsulation layer 117b may also be formed in an inkjet manner. However, the present disclosure is not limited thereto.

The third encapsulation layer 117c may be formed on the upper portion of the substrate 110 having the second encapsulation layer 117b to cover a top surface and a side surface of each of the second encapsulation layer 117b and the first encapsulation layer 117a. In this case, the third encapsulation layer 117c may minimize or block the penetration of outside moisture or oxygen into the first encapsulation layer 117a and the second encapsulation layer 117b. For example, the third encapsulation layer 117c may be made of an inorganic insulating material such as silicon nitride (SiNx), silicon oxide (SiOx), silicon oxynitride (SiON), or aluminum oxide (Al₂O₃).

A touch detection layer may be disposed on the encapsulation layer 117.

For example, a touch buffer layer 118a may be disposed on the third encapsulation layer 117c, and a touch electrode TE may be disposed on the touch buffer layer 118a.

The touch electrode TE may include a touch sensor metal TS and a bridge metal BM disposed on different layers. A touch interlayer insulation layer 118b may be disposed between the touch sensor metal TS and the bridge metal BM.

The touch buffer layer 118a and the touch interlayer insulation layer 118b may be disposed to remove a level difference at a point, at which the touch electrode TE is disposed, and implement appropriate electrical insulation.

Meanwhile, although not illustrated, a polarizing layer may be disposed on the touch detection layer.

The polarizing layer suppresses the reflection of external light in the display area DA of the substrate 110. In case that the display device 100 is used outside, external natural light may be introduced and reflected by the reflective layer included in the anode 121 of the light-emitting element 120 or reflected by an electrode made of metal and disposed on a lower portion of the light-emitting element 120. The light beams, which are reflected as described above, may inhibit an image on the display device 100 from being visually recognized. The polarizing layer may polarize, in a particular direction, the light introduced from the outside, thereby inhibiting the reflected light from being discharged again to the outside of the display device 100.

Although not illustrated, a cover glass may be bonded onto the polarizing layer by a bonding layer. The bonding layer may serve to bond the constituent elements of the display device 100. For example, the bonding layer may be formed by using a bonding agent for an optically transparent display such as a pressure-sensitive bonding agent, an optically transparent bonding agent (optical clear adhesive (OCR)), or an optically transparent resin (optical clear resin (OCR)). However, the present disclosure is not limited thereto.

The cover glass may protect the constituent elements of the display device 100 from external impact and suppress damage such as scratches.

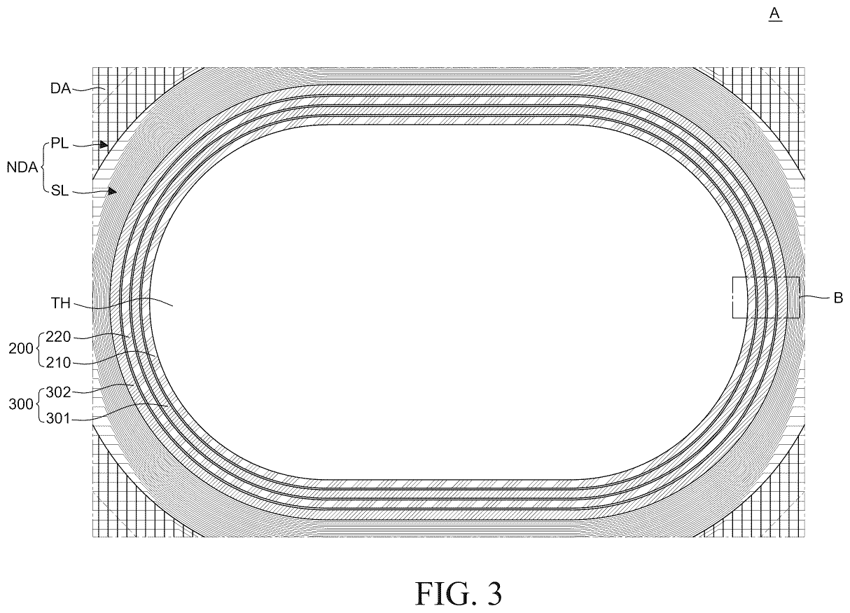

FIG. 3 is an enlarged top plan view illustrating area A corresponding to the optical area in FIG. 1 according to one embodiment.

With reference to FIG. 3, the through-hole TH for disposing an optical electronic device may be provided at a center of the optical area OA, and the camera module or sensor may be disposed in the through-hole TH. The optical area OA may include all areas in which a dam structure 300, which is adjacent to the circular or elliptical through-hole TH, an anti-connection part 200, and the like are disposed. The through-hole TH may be removed by a laser in a panel completion step. The non-display area NDA may be positioned between the through-hole TH and the display area DA, and a high-potential power line PL, a gate line SL, and the like may be disposed in the non-display area NDA. The anti-connection part 200 and the dam structure 300 may be disposed around the through-hole TH. With reference to FIG. 3, the anti-connection part 200 may include a first suppression part 210 and a second suppression part 220, and the dam structure 300 may include a first dam 301 and a second dam 302. The first suppression part 210, the first dam 301, the second suppression part 220, and the second dam 302 may be sequentially disposed based on the through-hole TH. In general, the dam structure may serve to maintain a bonding force between upper and lower substrates, which constitute the display panel DP, by inhibiting the second encapsulation layer 117b, which is a part of the encapsulation part 117 on the outer peripheral portion of the display panel DP, from flowing downward to an end of an outer peripheral portion of the display panel 100. The dam structure 300 in the optical area OA may also have a plurality of structures, such as the first dam 301 and the second dam 302, in order to inhibit the second encapsulation layer 117b of the encapsulation layer 117, which serves to protect the light-emitting element 150, from entering or leaking into the optical area OA. The anti-connection part 200 may be formed to suppress the penetration of moisture or oxygen by disconnecting the light-emitting layer 122. The present specification provides two dams. However, the present disclosure is not limited thereto. An additional dam may be disposed in accordance with an arrangement of a space. With reference to FIG. 3, the first suppression part 210 may be disposed to be close to the through-hole TH, and then the first dam 301, the second suppression part 220, and the second dam 302 may be sequentially disposed. The first suppression part 210 and the second suppression part 220 may be disposed to serve to protect the light-emitting element 120 in the display area from moisture or oxygen that may be introduced from the through-hole TH. The light-emitting layer 122 of the light-emitting element 120 may be deposited on a front surface of the display panel 100 and may also be uniformly deposited in the optical area OA. Because of the nature of the organic material, the light-emitting layer 122 has high reactivity and dispersity in respect to moisture and oxygen, such that moisture and oxygen may be transmitted to the light-emitting element 120 in the display area DA. The first and second suppression parts 210 and 220 may partially disconnect the light-emitting layer 122 to suppress the problem. In the present specification, the two suppression parts are illustrated. However, the present disclosure is not limited thereto.

The light-emitting element 120 and the pixel circuit in the corresponding area are removed to dispose the optical area OA. However, the light-emitting elements 120 and the pixel circuits disposed at upper, lower, left, and right sides based on the optical area OA need to be electrically connected. To this end, the high-potential power line PL, the gate line SL, and the like may be disposed in the non-display area NDA adjacent to the optical area OA so as to be connected at the upper, lower, left, and right sides while bypassing the optical area OA.

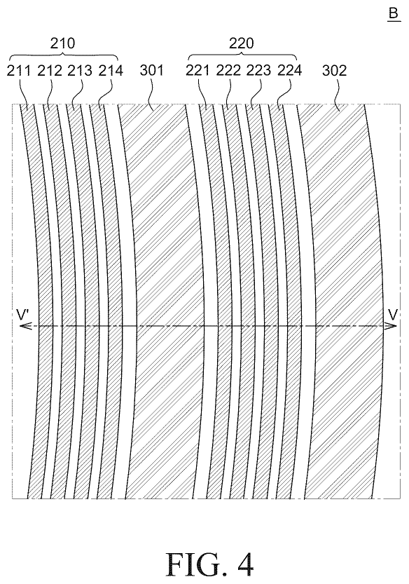

FIG. 4 is an enlarged top plan view of area B in FIG. 3 according to one embodiment.

With reference to FIG. 4, the first suppression part 210 may be disposed to be close to the through-hole TH, the first dam 301 may be disposed between the first suppression part 210 and the second suppression part 220, and the second dam 302 may be disposed at the right side of the second suppression part 220. The first suppression part 210 may include a first structure 211, a second structure 212, a third structure 213, and a fourth structure 214, and the second suppression part 220 may include a fifth structure 221, a sixth structure 222, a seventh structure 223, and an eighth structure 224. With reference to FIGS. 3 and 4, the first suppression part 210, the first dam 301, the second suppression part 220, and the second dam 302 may be disposed in a closed loop shape based on the through-hole TH. When any one of the first suppression part 210, the first dam 301, the second suppression part 220, and the second dam 302 is penetrated, moisture and oxygen may penetrate into the display area DA from the outside or the second encapsulation layer 117b may flow over the optical area OA and flow into the through-hole TH from the inside. Therefore, the first suppression part 210, the first dam 301, the second suppression part 220, and the second dam 302 are disposed in a closed loop shape. With reference to FIG. 4, the first suppression part 210 and the second suppression part 220 may each have four structures. However, the present disclosure is not limited thereto. For example, the first suppression part 210 and the second suppression part 220 may each have three or fewer or five or more structures. However, the present disclosure is not limited thereto.

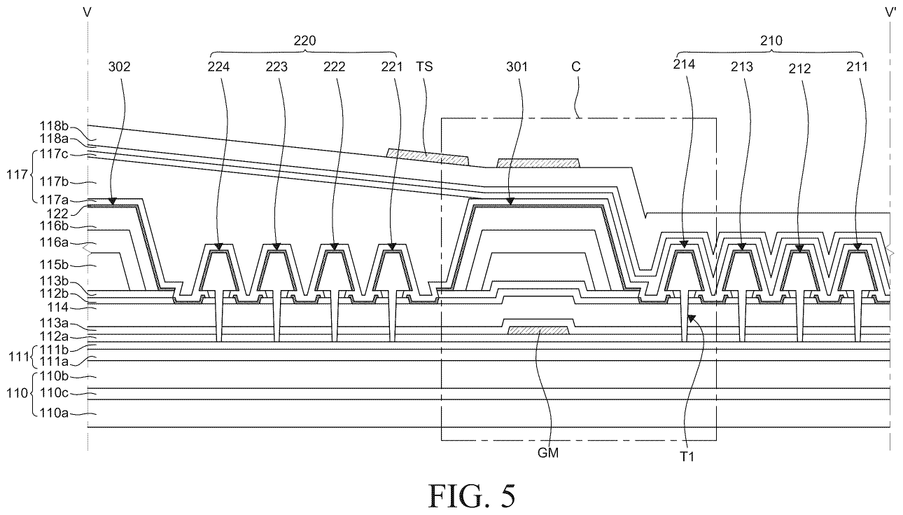

FIG. 5 is a cross-sectional view of the optical area taken along line V-V′ in FIG. 4 according to one embodiment.

The first suppression part 210 and the second suppression part 220 in a closed loop shape around the through-hole TH, the first dam 301 may be disposed between the first suppression part 210 and the second suppression part 220, and the second dam 302 may be disposed in a closed loop shape on another side surface of the second suppression part 220. With reference to FIG. 5, the through-hole TH may be disposed to be close to the first suppression part 210.

With reference to FIG. 4, the first suppression part 210 may include the first structure 211 to the fourth structure 214. The first to fourth structures 211, 212, 213, and 214 may each be formed as a two-stage structure including the upper and lower portions to disconnect the light-emitting layer 122, which may become a moisture penetration path for moisture from an area in which the through-hole TH is disposed, and define an undercut structure on a side surface of the upper portion. Specifically, the upper portion of each of the first to fourth structures 211, 212, 213, and 214 is disposed to have a cross-section with a trapezoidal shape having a tapered shape, and the lower portion of each of the first to fourth structures 211, 212, 213, and 214 is disposed to have a rectangular cross-section having an inversely tapered or approximately vertical side surface and having a predetermined height, such that a difference in width may occur between a bottom surface of the upper portion and a top surface of the lower portion that are points at which the upper and lower portions meet together. Because the top surface of the lower portion may be formed to be narrower than the bottom surface of the upper portion, the undercut structure, through which a part of the bottom surface of the upper portion is exposed, may be formed. Therefore, the light-emitting layer 122 deposited on the front surface of the display panel DP may be disconnected by the undercut structures of the side surfaces of the upper portions of the first to fourth structures 211, 212, 213, and 214.

The first to fourth structures 211, 212, 213, and 214, which constitute the first suppression part 210, may be made of an organic material and an inorganic material. For example, the upper portion of each of the first to fourth structures 211, 212, 213, and 214 may be made of the same material as the first planarization layer 115a or the second planarization layer 115b. However, the present disclosure is not limited thereto. In addition, the lower portion of each of the first to fourth structures 211, 212, 213, and 214 may be made of the same material as the second interlayer insulation layer 113b. However, the present disclosure is not limited thereto.

The second suppression part 220 may include the fifth to the eighth structures 221, 222, 223, and 224, respectively. The fifth to the eighth structures 221, 222, 223, and 224, which constitute the second suppression part 220, may each have a two-stage structure including the upper and lower portions, like the first to fourth structures 211, 212, 213, and 214. The second encapsulation layer 117b disposed on the second suppression part 220 may make it difficult for moisture or oxygen to penetrate the upper portion. Like the first suppression part 210, the second suppression part 220 may have an undercut structure formed in the side surface of the upper portion to block a path through which moisture or oxygen mainly penetrates into the through-hole TH or the side surface on which the first suppression part 210 is disposed. The arrangement of the first suppression part 210 and the second suppression part 220 may inhibit moisture or oxygen from penetrating into the light-emitting element 120 in the display area DA from the optical area OA through the light-emitting layer 122.

The fifth to eighth structures 221, 222, 223, and 224, which constitute the second suppression part 220, may also be made of an organic material and an inorganic material. For example, the upper portion of each of the fifth to eighth structures 221, 222, 223, and 224 may be made of the same material as the first planarization layer 115a or the second planarization layer 115b. However, the present disclosure is not limited thereto. The lower portion of each of the fifth to eighth structures 221, 222, 223, and 224 may be made of the same material as the second interlayer insulation layer 113b. However, the present disclosure is not limited thereto.

As illustrated in FIG. 5, the first dam 301 and the second dam 302 may be formed by stacking the second planarization layer 115b, the bank 116a, and the spacer 116b. However, the present disclosure is not limited thereto. The first dam 301 and the second dam 302 may further include the first planarization layer 115a and further include other layers.

With reference to FIG. 3, the optical area OA may vary depending on a size of a camera to be applied to a product. The corresponding area is illustrated as an empty space, but some insulation films or wiring structures may be disposed in the area. However, a separation description of a dummy area is omitted because the dummy area does not remain in the finished product when the through-hole TH is removed by a laser. The laser beams may be emitted in a circular or elliptical shape depending on the shape of the optical area OA. All the areas on the substrate including the substrate 110 may be removed by the emitted laser beams. There may be a difference between the actual optical area OA and a laser irradiation area. For example, the laser irradiation area of the optical area OA may be an area formed inward by about 100 μm. The difference needs to be defined between the laser irradiation area and the optical area OA so that the insulation layer of the optical area OA is not damaged during the laser irradiation. A picosecond laser or a femtosecond laser may be used as the laser. However, the present disclosure is not limited thereto. The laser refers to a device that amplifies light generated by applying energy to a particular material and uses light induced and emitted. The laser beams have the same characteristics as radio waves and have directionality of monochromatic light. Therefore, the laser is used for communication, medical, or industrial purposes. A pattern may be easily formed on a desired portion or a particular site may be easily removed by using the laser. The laser utilizes energy to form or remove patterns. When the energy of the laser is emitted onto the object, heat energy melts an object to form patterns. The longer the laser beams are applied, the more thermal effects may occur that are transferred to neighboring areas in which the patterns are formed. This thermal effect is the accumulation of heat around a laser irradiation area of an object, and the heat may burn or deform the surrounding area larger than the set pattern. Because of these characteristics of lasers, in case that the area being irradiated by the laser overlaps or is adjacent to an insulation film, the thermal energy of the laser may deform the insulation film. The deformation of the insulation film may cause cracks, and the cracks may propagate through the insulation film, which may cause separation of the insulation film and subsequent penetration of moisture and oxygen. For example, in order to suppress the deformation or separation of the insulation films, such as the multi-buffer layer 111a, the active buffer layer 111b, the first gate insulation layer 112a, the first interlayer insulation layer 113a, the second buffer layer 114, the second gate insulation layer 112b, and the second interlayer insulation layer 113b, all the insulation films may be removed with a distance of about 100 μm from a laser irradiation position.

There is a problem in that a crack, which occurs when the substrate 110 is cut by a laser, propagates through the inorganic insulation layer. Moisture or oxygen is characterized by reacting with and transferred to the light-emitting layer 122 of the light-emitting element 120, whereas cracks may be transferred through hard inorganic insulation layers that are not flexible. Alternatively, when the camera or sensor is assembled to the through-hole TH formed by a laser, cracks may occur because of interference. The cracks, which occur as described above, may also propagate through the inorganic insulation layer. In case that the cracks occurring in the through-hole TH propagate through the inorganic insulation layer, a line defect or a growing dark spot (GDS) defect may occur.

Therefore, in the display device 100 according to the embodiment of the present specification, first trenches T1l may be disposed in some of the plurality of insulation layers disposed in the optical area OA, such that stepped structures are formed on the plurality of insulation layers, which may block crack propagation paths.

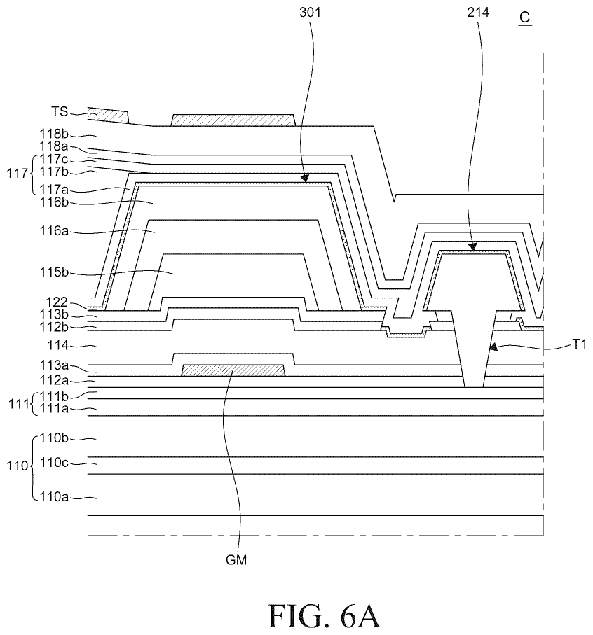

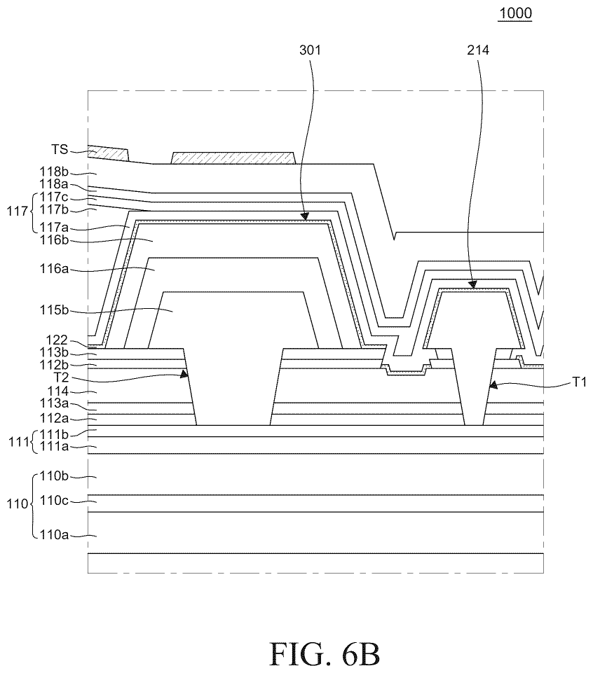

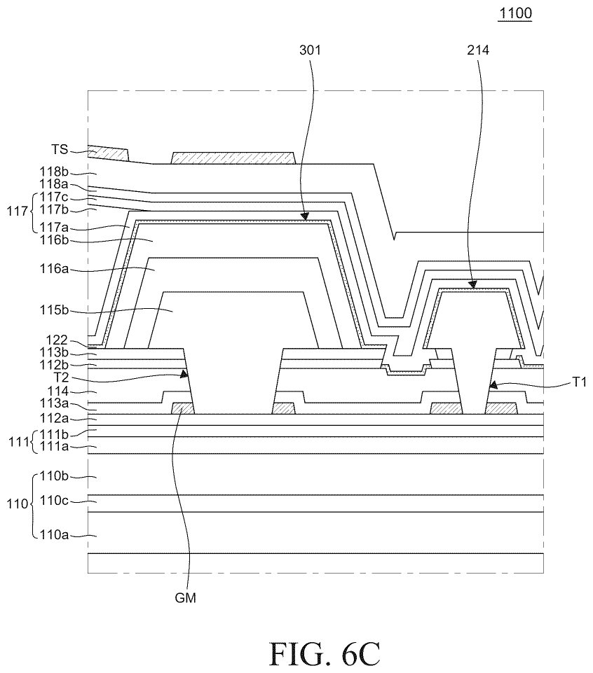

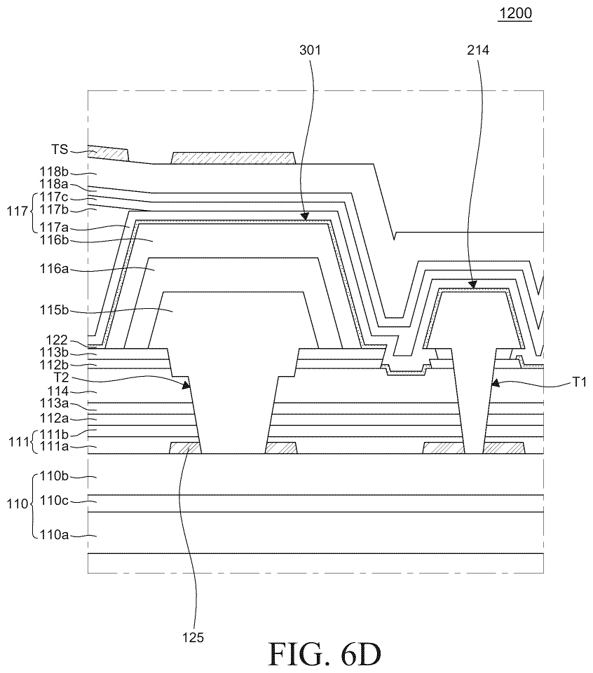

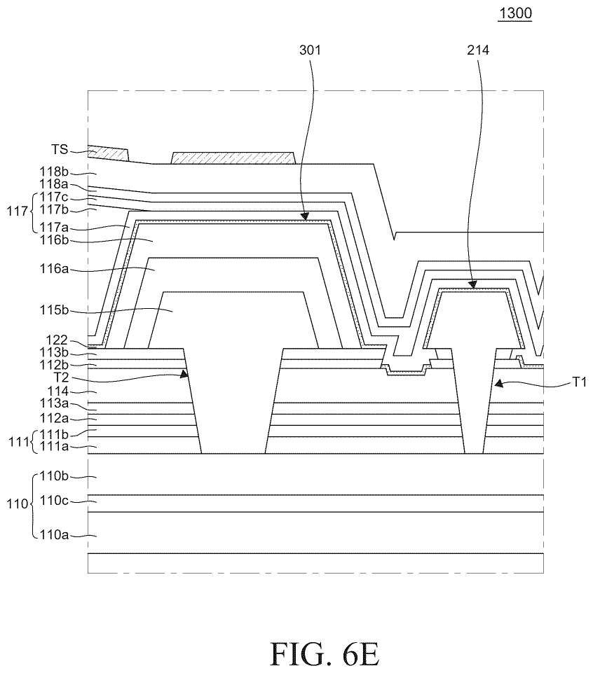

FIG. 6A is an enlarged cross-sectional view of area C in FIG. 5 according to the embodiment of the present specification.

With reference to FIGS. 5 and 6A, according to the embodiment of the present specification, the first trenches T1 may be disposed in some of the plurality of insulation layers that overlap at least one anti-connection part 200 in the optical area OA. For example, the plurality of insulation layers may be at least one the first buffer layer 111, the first gate insulation layer 112a, the first interlayer insulation layer 113a, the second buffer layer 114, the second gate insulation layer 112b, and the second interlayer insulation layer 113b disposed on the substrate 110, and the first trenches T1 may be disposed in some insulation layers disposed at the upper side among the plurality of insulation layers.

Specifically, with reference to FIGS. 3 and 6A together, the first trench T1 may be provided by at least partially etching the plurality of insulation layers, i.e., the first gate insulation layer 112a, the first interlayer insulation layer 113a, the second buffer layer 114, the second gate insulation layer 112b, and the second interlayer insulation layer 113b that overlap at least one anti-connection part 200 disposed in the optical area OA.

The stepped structures may be formed on the plurality of insulation layers by the first trenches T1. Therefore, even though the through-hole TH cracks, the propagation of the crack may be suppressed because the inorganic insulation layer, through which the crack may propagate, is removed from the area in which the first trenches T1 are formed.

In addition, according to the embodiment of the present specification, at least any one of the first planarization layer 115a and the second planarization layer 115b may be disposed in the first trench T1 to fill the first trench T1.

According to the embodiment of the present specification, the first trenches T1 may be formed by at least partially removing the plurality of inorganic insulation layers through which cracks may propagate, and the inside of the first trench T1 is filled with an organic material. Therefore, even though the through-hole TH cracks, the crack may not propagate any further in the first trench T1.

FIGS. 5 and 6A illustrate a first trench disposed in the optical area OA. However, the first trench in the optical area OA according to the embodiment of the present specification is not limited thereto.

FIG. 6B is a cross-sectional view of a display device according to another embodiment of the present specification. FIG. 6C is a cross-sectional view of a display device according to still another embodiment of the present specification. FIG. 6D is a cross-sectional view of a display device according to yet another embodiment of the present specification. FIG. 6E is a cross-sectional view of a display device according to still yet another embodiment of the present specification.

As illustrated in FIG. 6B, a display device 1000 according to another embodiment of the present specification may further include the first trench T1 configured to overlap at least one anti-connection part 200 disposed in the optical area OA, and a second trench T2 disposed in some of the plurality of insulation layers that overlaps the dam structure 300 disposed in the optical area OA.

Specifically, as illustrated in FIG. 6B, the optical area OA may include the first trench T1 made by at least partially etching the first gate insulation layer 112a, the first interlayer insulation layer 113a, the second buffer layer 114, the second gate insulation layer 112b, and the second interlayer insulation layer 113b that overlap at least one anti-connection part 200, and the second trench T2 made by at least partially etching the first gate insulation layer 112a, the first interlayer insulation layer 113a, the second buffer layer 114, the second gate insulation layer 112b, and the second interlayer insulation layer 113b that overlap the dam structure 300.

Therefore, in the display device 1000 according to another embodiment of the present specification, the first trench T1 and the second trench T2 are disposed in the optical area OA. Therefore, even though cracks occur at the time of forming the through-hole TH in the optical area OA or assembling an optical electronic device to the through-hole TH, the crack propagation path is blocked by the first trench T1 and the second trench T2, which may suppress a defect caused by the crack propagation.

For example, after the plurality of insulation layers is formed, depths of the first trenches T1 and the second trenches T2 formed in some of the plurality of insulation layers may be adjusted by using a mask process. In this case, the first trench T1 and the second trench T2 may be formed by the same mask process.

The depths of the first and second trenches T1 and T2 may be adjusted by changing the condition of the mask process, as necessary.

FIG. 6C is a cross-sectional view of a display device according to still another embodiment of the present specification.

As illustrated in FIG. 6C, in a display device 1100 according to still another embodiment of the present specification, the first trench T1 and the second trench T2 may overlap at least one anti-connection part 200 and the dam structure 300 and be at least partially disposed on the gate metal GM disposed on the same layer as the gate electrode G1 of the first thin-film transistor, the first interlayer insulation layer 113a, the second buffer layer 114, the second gate insulation layer 112b, and the second interlayer insulation layer 113b.

FIG. 6D is a cross-sectional view of a display device according to yet another embodiment of the present specification. FIG. 6E is a cross-sectional view of a display device according to still yet another embodiment of the present specification.

As illustrated in FIG. 6D, in a display device 1200 according to yet another embodiment of the present specification, the first trench T1 and the second trench T2 may overlap at least one anti-connection part 200 and the dam structure 300 and be at least partially disposed on the light-blocking layer 125, the first buffer layer 111, the first gate insulation layer 112a, the first interlayer insulation layer 113a, the second buffer layer 114, the second gate insulation layer 112b, and the second interlayer insulation layer 113b.

FIG. 6E is a cross-sectional view of a display device according to still yet another embodiment of the present specification.

As illustrated in FIG. 6E, in a display device 1300 according to yet another embodiment of the present specification, the first trench T1 and the second trench T2 may overlap at least one anti-connection part 200 and the dam structure 300 and be at least partially disposed on the first buffer layer 111, the first gate insulation layer 112a, the first interlayer insulation layer 113a, the second buffer layer 114, the second gate insulation layer 112b, and the second interlayer insulation layer 113b.

Therefore, according to still yet another embodiment of the present specification, the first trench T1 and the second trench T2 are disposed in the optical area OA. Therefore, even though cracks occur at the time of forming the through-hole TH in the optical area OA or assembling an optical electronic device to the through-hole TH, the crack propagation path is blocked by the first trench T1 and the second trench T2, which may suppress a defect caused by the crack propagation.

In addition, according to still yet another embodiment of the present specification, the first trench T1 and the second trench T2 are disposed in the optical area OA so as to overlap at least one anti-connection part 200 and the dam structure 300, such that a separate space for suppressing crack propagation is not required, and the non-display area NDA adjacent to the optical area OA may be minimized or at least reduced.

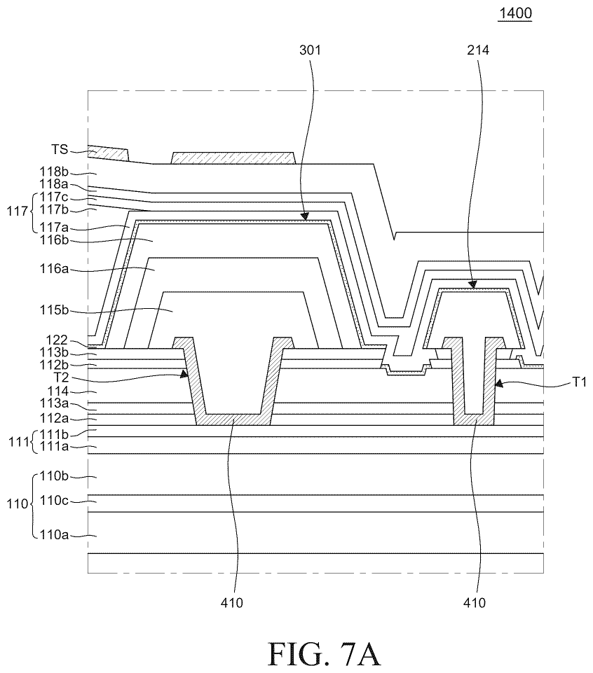

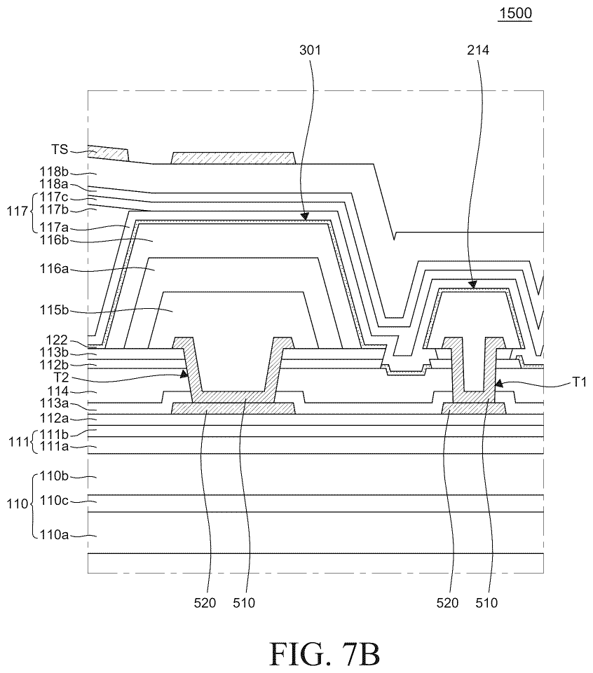

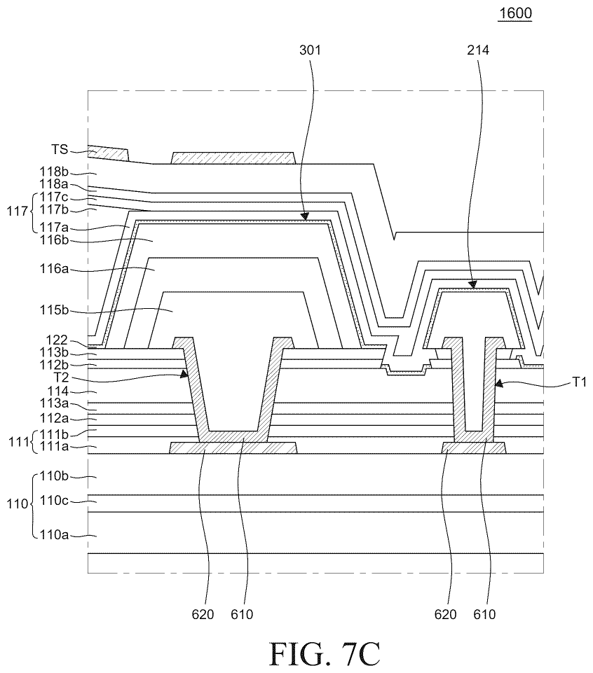

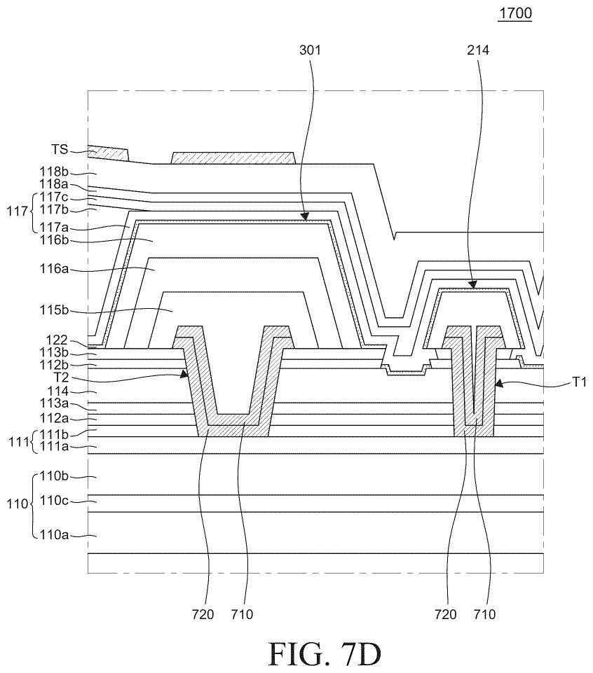

Hereinafter, a more detailed description of the optical area OA of the display device according to yet another embodiment of the present specification will be described with reference to FIG. 7.

FIG. 7A is a cross-sectional view of a display device according to a further embodiment of the present specification. FIG. 7B is a cross-sectional view of a display device according to another further embodiment of the present specification. FIG. 7C is a cross-sectional view of a display device according to still another further embodiment of the present specification. FIG. 7D is a cross-sectional view of a display device according to yet another further embodiment of the present specification. The cross-sectional views in FIGS. 7A to 7D are substantially identical in configuration to the cross-sectional views in FIGS. 6A to 6E, except for first and second metal layers. Therefore, for convenience of description, a repeated description excluding the first and second metal layer will be omitted.

In a display device 1400 according to a further embodiment of the present specification may further include first metal layers 410 disposed in the first and second trenches T1 and T2 and disposed along surfaces of some of the plurality of insulation layers.

For example, the first metal layers 410 may be disposed in the first and second trenches T1 and T2 and adjoin the surfaces of the plurality of insulation layers.

As illustrated in FIG. 7A, the first metal layers 410 may be disposed in the first and second trenches T1 and T2 and adjoin the surfaces of the plurality of insulation layers. For example, the first metal layer 410 may be made of the same material as the first source electrode S1 and the first drain electrode D1 of the first thin-film transistor TR1.

In the display device 1400 according to a further embodiment of the present specification, the crack propagation path may be blocked by the stepped structures of the plurality of insulation layers made by the first and second trenches T1 and T2, and the crack propagation may be further additionally blocked by the first metal layers 410 disposed in the first and second trenches T1 and T2 so as to adjoin the surfaces of the plurality of insulation layers. Therefore, even though cracks occur at the time of forming the through-hole TH in the optical area OA or assembling the optical electronic device to the through-hole TH, the crack propagation path may be completely blocked by the first trench T1, the second trench T2, and the first metal layer 410, which may suppress a defect caused by crack propagation.

FIG. 7A illustrates the structures of the first metal layers 410 disposed in the first and second trenches T1 and T2 in the optical area OA and disposed along the surfaces of some of the plurality of insulation layers. However, the structure of the optical area OA according to the embodiment of the present specification is not limited thereto.

FIG. 7B is a cross-sectional view of a display device according to another further embodiment of the present specification.

A display device 1500 according to another further embodiment of the present specification may further include second metal layers 520 disposed below the first and second trenches T1 and T2 in the optical area OA.

For example, as illustrated in FIG. 7B, first metal layers 510 may be disposed in the first and second trenches T1 and T2 and adjoin the side surfaces of some of the plurality of insulation layers. The first metal layer 510 and the second metal layer 520 may adjoin each other. For example, the first metal layer 510 may be disposed on the same layer and made of the same material as the first source electrode S1 and the first drain electrode D1, and the second metal layer 520 may be disposed on the same layer and made of the same material as the first gate electrode G1.

In the display device 1500 according to another further embodiment of the present specification, the crack propagation path may be blocked by the stepped structures of the plurality of insulation layers made by the first and second trenches T1 and T2, and the crack propagation path may be further additionally blocked by the first metal layers 510 disposed in the first and second trenches T1 and T2 and the second metal layers 520 disposed below the first and second trenches T1 and T2. Therefore, even though cracks occur at the time of forming the through-hole TH in the optical area OA or assembling the optical electronic device to the through-hole TH, the crack propagation path may be completely blocked by the first trench T1, the second trench T2, the first metal layer 510, and the second metal layer 520, which may suppress a defect caused by crack propagation.

According to another further embodiment of the present specification, the depths of the first and second trenches T1 and T2 disposed in some of the plurality of insulation layers may be adjusted. In this case, the materials for forming the first and second metal layers 510 and 520 may vary depending on the depths of the first and second trenches T1 and T2.

FIG. 7C is a cross-sectional view of a display device according to still another further embodiment of the present specification. As illustrated in FIG. 7C, in a display device 1600 according to still another further embodiment of the present specification, a first metal layer 610 may be made of the same material as the first source electrode S1 and the first drain electrode D1, and a second metal layer 620 may be made of the same material as the light-blocking layer 125.

FIG. 7D is a cross-sectional view of a display device according to yet another further embodiment of the present specification. As illustrated in FIG. 7D, in a display device 1700 according to yet another further embodiment of the present specification, second metal layers 720 may be disposed in the first and second trenches T1 and T2 and adjoin the surfaces of the plurality of insulation layers, and first metal layers 710 may be disposed in the first and second trenches T1 and T2 and adjoin the surfaces of the second metal layers 720. For example, the first metal layer 710 may be disposed on the same layer and made of the same material as the second source electrode S2 and the second drain electrode D2, and the second metal layer 720 may be disposed on the same layer and made of the same material as the first source electrode S1 and the first drain electrode D1.

Therefore, according to still yet another embodiment of the present specification, the first trench T1 and the second trench T2 are disposed in the optical area OA. Therefore, even though cracks occur at the time of forming the through-hole TH in the optical area OA or assembling an optical electronic device to the through-hole TH, the crack propagation path is blocked by the first trench T1 and the second trench T2, which may suppress a defect caused by the crack propagation. In addition, the first trench T1 and the second trench T2 are disposed in the optical area OA so as to overlap at least one anti-connection part 200 and the dam structure 300, such that a separate space for suppressing crack propagation is not required, and the non-display area NDA adjacent to the optical area OA may be minimized or at least reduced.

In addition, according to still yet another further embodiment of the present specification, the first metal layers 410, 510, 610, and 710 may be disposed in the first and second trenches T1 and T2, and the second metal layers 420, 520, 620, and 720 may be disposed to adjoin the first metal layers 410, 510, 610, and 710, such that the crack propagation may be further blocked. Therefore, even though cracks occur at the time of forming the through-hole TH in the optical area OA or assembling the optical electronic device to the through-hole TH, the crack propagation path may be completely blocked by the first trench T1, the second trench T2, the first metal layers 410, 510, 610, and 710, and the second metal layers 420, 520, 620, and 720, which may suppress a defect caused by crack propagation.

The exemplary embodiments of the present disclosure can also be described as follows:

According to as aspect of the present disclosure, a display device includes a substrate including a display area, an optical area disposed in the display area and including a through-hole, and a non-display area configured to surround the display area, a plurality of insulation layers disposed on the substrate, at least one dam disposed on the plurality of insulation layers, and at least one anti-connection part disposed on the plurality of insulation layers and disposed to be closer to the through-hole than the at least one dam, in which first trenches are disposed in some of the plurality of insulation layers that overlaps the at least one anti-connection part in the optical area.

The plurality of insulation layers may comprise at least one of a first buffer layer, a first gate insulation layer, a first interlayer insulation layer, a second buffer layer, a second gate insulation layer, and a second interlayer insulation layer disposed on the substrate, and the first trenches are disposed in some insulation layers disposed at an upper side among the plurality of insulation layers.

The display device may further include a second trenches disposed in some of the plurality of insulation layers that overlaps the at least one dam in the optical area.

The display device may further include a first metal layers disposed in each of the first and second trenches and disposed along surfaces of some of the plurality of insulation layers.

The first metal layers are disposed in each of the first and second trenches and may adjoin the surfaces of the plurality of insulation layers.

The display device may further include a first thin-film transistor disposed on the substrate in the display area and comprising a first active layer, a first gate electrode, a first source electrode, and a first drain electrode, at least one insulation layer disposed on the first gate electrode, and a second thin-film transistor disposed on the at least one insulation layer and comprising a second active layer, a second gate electrode, a second source electrode, and a second drain electrode.

The first metal layer may be made of the same material as the first source electrode and the first drain electrode.

The display device may further include a second metal layers disposed below each of the first and second trenches.

The first metal layers are disposed in each of the first and second trenches and adjoin side surfaces of some of the plurality of insulation layers, and the first metal layer and the second metal layer may adjoin each other.

The first metal layer is disposed on the same layer and made of the same material as the first source electrode and the first drain electrode, and the second metal layer may be disposed on the same layer and made of the same material as the first gate electrode.

The display device may further include a light-blocking layer disposed below the first active layer so as to overlap the first gate electrode, the first metal layer may be made of the same material as the first source electrode and the first drain electrode, and the second metal layer may be made of the same material as the light-blocking layer.

The second metal layers are disposed in each of the first and second trenches and adjoin surfaces of the plurality of insulation layers, and the first metal layers disposed in each of the first and second trenches and may adjoin surfaces of the second metal layers.

The first metal layer is disposed on the same layer and made of the same material as the second source electrode and the second drain electrode, and the second metal layer may be disposed on the same layer and made of the same material as the first source electrode and the first drain electrode.

The display device may further include an optical electronic device disposed to overlap the optical area.

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. The protective scope of the present disclosure should be construed based on the following claims, and all the technical concepts in the equivalent scope thereof should be construed as falling within the scope of the present disclosure.

What is claimed is:

1. A display device comprising:
a substrate including a display area, an optical area in the display area and including a through-hole, and a non-display area that surrounds the display area;
a plurality of insulation layers on the substrate;
at least one dam on the plurality of insulation layers; and
at least one anti-connection part on the plurality of insulation layers, the at least one anti-connection part closer to the through-hole than the at least one dam,
wherein first trenches are in some of the plurality of insulation layers that overlap the at least one anti-connection part in the optical area.

2. The display device of claim 1, wherein the plurality of insulation layers comprise at least one of a first buffer layer, a first gate insulation layer, a first interlayer insulation layer, a second buffer layer, a second gate insulation layer, and a second interlayer insulation layer on the substrate, and
wherein the first trenches are in some insulation layers from the plurality of insulation layers that are at an upper side among the plurality of insulation layers.

3. The display device of claim 1, further comprising:
second trenches in some of the plurality of insulation layers from the plurality of insulation layers that overlap the at least one dam in the optical area.

4. The display device of claim 2, further comprising:
a first thin-film transistor on the substrate in the display area, the first thin-film transistor comprising a first active layer, a first gate electrode, a first source electrode, and a first drain electrode;
at least one insulation layer on the first gate electrode; and
a second thin-film transistor on the at least one insulation layer, the second thin-film transistor comprising a second active layer, a second gate electrode, a second source electrode, and a second drain electrode;
a first planarization layer above the first source electrode and the first drain electrode of the first thin-film transistor, and the second source electrode and the second drain electrode of the second thin-film transistor, and
a second planarization layer above the first planarization layer,
wherein at least any one of the first planarization layer and the second planarization layer is in a first trench from the first trenches and fills the first trench.

5. The display device of claim 3, further comprising:
first metal layers in each of the first trenches and the second trenches, the first metal layers along surfaces of some of the plurality of insulation layers.

6. The display device of claim 5, wherein the first metal layers are in each of the first trenches and the second trenches and adjoin the surfaces of the plurality of insulation layers.

7. The display device of claim 6, further comprising:
a first thin-film transistor on the substrate in the display area, the first thin-film transistor comprising a first active layer, a first gate electrode, a first source electrode, and a first drain electrode;
at least one insulation layer on the first gate electrode; and
a second thin-film transistor on the at least one insulation layer, the second thin-film transistor comprising a second active layer, a second gate electrode, a second source electrode, and a second drain electrode.

8. The display device of claim 7, wherein a first metal layer from the first metal layers is made of a same material as the first source electrode and the first drain electrode.

9. The display device of claim 7, further comprising:
second metal layers below each of the first trenches and the second trenches.

10. The display device of claim 9, wherein the first metal layers are in each of the first trenches and the second trenches and adjoin side surfaces of some of the plurality of insulation layers, and the first metal layers and the second metal layers adjoin each other.

11. The display device of claim 10, wherein a first metal layer from the first metal layers is on a same layer and made of a same material as the first source electrode and the first drain electrode, and a second metal layer from the second metal layers is on a same layer and made of a same material as the first gate electrode.

12. The display device of claim 10, further comprising:
a light-blocking layer below the first active layer and overlaps the first gate electrode,
wherein a first metal layer from the first metal layers is made of a same material as the first source electrode and the first drain electrode, and
wherein a second metal layer from the second metal layers is made of a same material as the light-blocking layer.

13. The display device of claim 10, wherein the second metal layers are in each of the first trenches and the second trenches and adjoin surfaces of the plurality of insulation layers, and the first metal layers are in each of the first trenches and the second trenches and adjoin surfaces of the second metal layers.

14. The display device of claim 13, wherein a first metal layer from the first metal layers is on a same layer and made of a same material as the second source electrode and the second drain electrode, and a second metal layer from the second metal layers is on a same layer and made of a same material as the first source electrode and the first drain electrode.

15. The display device of claim 1, further comprising:
an optical electronic device that overlaps the optical area.

16. The display device of claim 15, wherein,
the through-hole corresponds to the optical electronic device.
